(19) United States
(12) Patent Application Publication
(10) Pub. No.: US 2011/0294248 A1
(43) Pub. Date: Dec. 1, 2011

(54) METHOD FOR HEATING A SUBSTRATE OF SOLAR CELL

(76) Inventor: Seung-Yeop Myong, Seoul (KR)

(21) Appl. No.: 13/118,000

(22) Filed: May 27, 2011

(30) Foreign Application Priority Data
May 31, 2010 (KR) 10-2010-0050957

(51) Int. Cl. H01L 31/18

(52) U.S. Cl. 438/71; 257/E31.13

(57) ABSTRACT

Disclosed is a method for heating a substrate of a solar cell. The method includes: providing a single or poly crystalline substrate; heating the substrate at atmosphere by a non-contact heater; and forming a thin film, which includes amorphous silicon or silicon alloy, on the substrate.

### CROSS-REFERENCE TO RELATED APPLICATIONS

This application claims priority under 35 U.S.C. §119 to Korean Patent Application No. 10-2010-0050957 filed on May 31, 2010, the entirety of which is hereby incorporated by reference.

### FIELD OF THE INVENTION

The present invention relates to a method for heating a substrate of a solar cell.

### BACKGROUND OF THE INVENTION

Recently, as existing energy resources like oil and coal and the like are expected to be exhausted, much attention is increasingly paid to alternative energy sources which can be used in place of the existing energy sources. As an alternative energy source, sunlight energy is abundant and has no environmental pollution. Therefore, more and more attention is paid to the sunlight energy.

A photovoltaic device is a solar cell that directly converts sunlight energy into electrical energy. The photovoltaic device mainly uses photovoltaic effect of semiconductor junction. In other words, when light is incident on and absorbed by a semiconductor p-n junction doped with p-type impurity and n-type impurity respectively, light energy generates electrons and holes within the semiconductor and the electrons and the holes are separated from each other by an internal electric field. As a result, a photo-electro motive force is generated between both ends of the p-n junction. Here, when electrodes are formed at both ends of the junction and connected with wires, electric current flows externally through the electrodes and the wires.

In order that the existing energy sources such as oil is substituted with the sunlight energy source, it is necessary to provide a photovoltaic device with high photovoltaic conversion efficiency.

### SUMMARY OF THE INVENTION

One aspect of the present invention is a method for heating a substrate of a solar cell. The method includes: providing a single or poly crystalline substrate; heating the substrate at atmosphere by a non-contact heater; and forming a thin film, which includes amorphous silicon or silicon alloy, on the substrate.

Another aspect of the present invention is a method for heating a substrate of a solar cell. The method includes: providing a single or poly crystalline substrate which has been doped with a first conductive impurity and a second conductive impurity; heating the substrate at atmosphere by, a non-contact heater; and forming a thin film, which includes silicon alloy, on the substrate.

Further another aspect of the present invention is a method for heating a substrate of a solar cell. The method includes: providing a single or poly crystalline substrate which has been doped with a first conductive impurity; heating the substrate at atmosphere by a non-contact heater; forming an intrinsic amorphous silicon layer on the substrate; and forming a second conductive impurity doped-amorphous silicon layer on the intrinsic amorphous silicon layer.

### BRIEF DESCRIPTION OF THE DRAWINGS

FIG. 1 shows a method for heating a substrate of a solar cell in accordance with an embodiment of the present invention.

FIGS. 2a to 2d show a method for heating a substrate of a solar cell in accordance with an embodiment of the present invention.

FIGS. 3a to 3e show a method for heating a substrate of a solar cell in accordance with an embodiment of the present invention.

FIG. 4 shows a modified example of the solar cell of an embodiment of the present invention.

### DETAILED DESCRIPTION

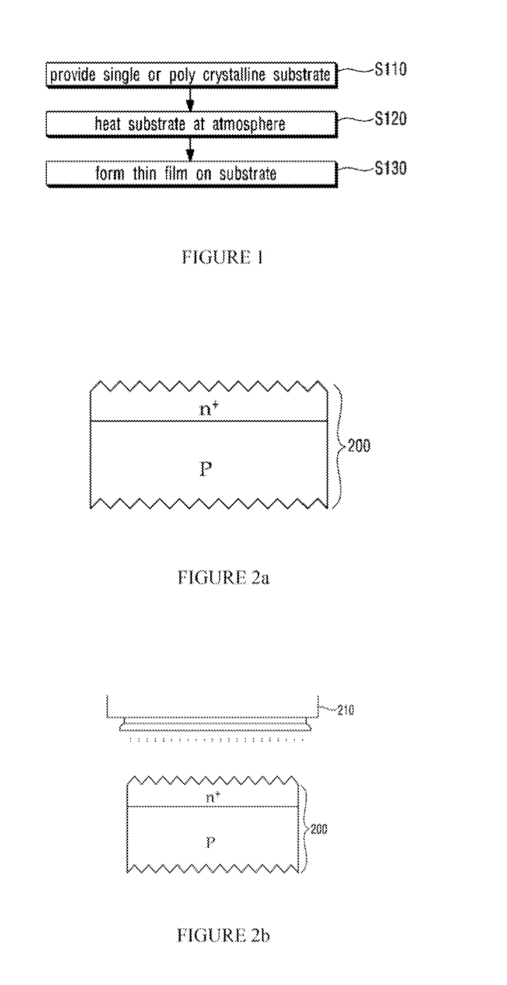

An embodiment of the present invention will be described in detail with reference to the drawings. FIG. 1 shows a method for heating a substrate of a solar cell in accordance with an embodiment of the present invention.

A single crystalline substrate or a poly crystalline substrate is provided (S110). Here, the single crystalline substrate or the poly crystalline substrate may be doped with, a first conductive impurity and a second conductive impurity. When the first conductive impurity is a p-type impurity like group III element, the second conductive impurity is an n-type impurity like group V element. When the first conductive impurity is an n-type impurity like group V element the second conductive impurity is a p-type impurity like group III element. As such, the p-type impurity and the n-type impurity are doped in the single crystalline substrate or the poly crystalline substrate, so that p-n junction is formed in the substrate.

The single crystalline substrate or the poly crystalline substrate may be doped with a first conductive impurity. Here, the first conductive impurity includes a p-type impurity like group III element or an n-type impurity like group V element. As such, the first conductive impurity is doped in the single crystalline substrate or the poly crystalline substrate, so that p-n junction is not formed in the substrate.

The substrate is heated at atmosphere by a non-contact heater (S120). Here, the substrate can be heated by the non-contact heater at atmosphere during the transfer of the substrate. Unlike the embodiment of the present invention, when the substrate is heated by a contact heater, the contact heater should contact with the substrate. Therefore, the transfer of the substrate is stopped, and then the substrate is heated. Here, in order to prevent pollution, it is necessary to perform the heating of the substrate in a vacuum state. On the contrary to this, in the embodiment of the present invention, the substrate is heated without contacting with the heater at atmosphere instead of vacuum, so that the substrate can be heated during the transfer thereof without having to maintain vacuum to prevent pollution. As a result, it is possible to reduce the tact time and manufacturing cost of the solar cell.

The non-contact heater of the embodiment of the present invention may include an infrared (IR) oven. The IR oven is not expensive and is able to heat the substrate at atmosphere instead of vacuum.

A thin film including amorphous silicon or silicon alloy, is formed on the substrate (S130). Here, the thin film including the silicon alloy can be formed on the single crystalline substrate or the poly crystalline substrate which has been doped with the first conductive impurity and the second conductive impurity. For example, the thin film including SiOx or SiNx may be formed on the substrate, in which the pn junction has been formed. When the refractive index of the silicon, alloy is less than that of the substrate, the thin film including the silicon alloy can function as a passivation layer and an anti-reflective layer.

Further, an intrinsic amorphous silicon layer may be formed on the single crystalline substrate or the poly crystalline substrate which has been doped with a first conductive impurity, and then an amorphous silicon layer doped with a second conductive impurity may be formed on the intrinsic amorphous silicon layer. Here, when the first conductive impurity is a p-type impurity like group III element, the second conductive impurity is an n-type impurity like group V element. When the first conductive impurity is an n-type impurity like group V element, the second conductive impurity is a p-type impurity like group III element.

In the next place, the following detailed description will focus on a case where the embodiment of the present invention is using a single crystalline substrate or a poly crystalline substrate which has been doped with a first conductive impurity and a second conductive impurity.

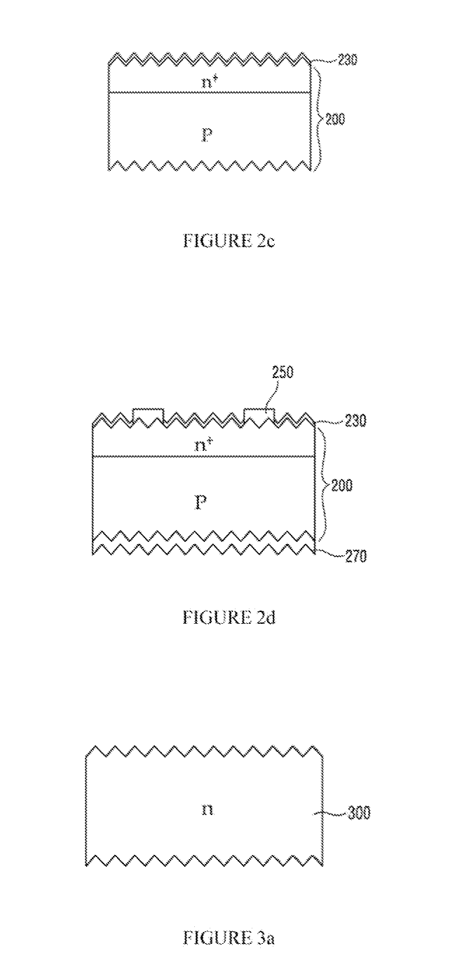

As shown in FIG. 2a, provided is, the single crystalline substrate or the poly crystalline substrate which has been doped with the first conductive impurity and the second conductive impurity.

In order to reduce the amount of reflected light by scattering sunlight incident on the surface of the substrate 200, a texturing process is performed on the surface of the substrate 200 so that the surface of the substrate 200 is textured. The texturing process is performed by means of a wet etching process that makes use of an alkaline solution such as KOH or NaOH, or an acid solution such as HNO₃ or HF.

The second conductive impurity is doped in the substrate 200 which has been doped with the first conductive, impurity. Although FIG. 2a shows that the n-type impurity is doped in the p-type impurity-doped substrate 200, the p-type impurity can be doped in the n-type impurity-doped substrate 200. The impurity can be doped by exposing at a high temperature the surface of the substrate 200 to, gas or solid that includes group III impurity or group V impurity. Additionally, the impurity can be also doped by ion implantation that is performed by placing the substrate 200 in a vacuum chamber, accelerating impurity ions and implanting the impurity into the surface of the substrate 200.

As shown in FIG. 2b, the impurity-doped substrate 200 is heated at atmosphere by a non-contact heater 210.

With the intention of activating an interface between the substrate 200 and the silicon alloy to be formed layer, of increasing the passivation effect at the interface, and of removing moisture that is absorbed by the substrate 200 during the etching process and the like, the substrate 200 is heated at atmosphere by the non-contact heater 210 before the silicon alloy is formed on the textured substrate 200. As described above, since the substrate 200 is heated at atmosphere without contacting with the heater, the substrate can be heated during the transfer thereof without having to maintain vacuum for heating. The non-contact heater of the embodiment of the present invention may include an infrared (IR) oven.

The temperature of the substrate 200 is equal to or higher than 120° and is equal to or lower than 200° during the heating process of the substrate 200. The substrate 200 is heated for equal to or greater than 60 seconds and equal to or less than 600 seconds. When the temperature of the substrate 200 is equal to or higher than 120° and the heating time of the substrate 200 is equal to or, greater than 60 second, the moisture of the substrate 200 can be fully removed. When the temperature of the substrate 200 is equal to or lower than 200° and the heating time of the substrate 200 is equal to or less than 600 seconds, it is possible to reduce the influence on the operating reliability of a PECVD apparatus in which a thin film 230 is formed in the following process. That is, when the substrate 200 is excessively heated, the quality of film formed in a PECVD apparatus may be degraded due to the temperature of the substrate 200.

As shown in FIG. 2c, a thin film 230 including the silicon alloy such as SiOx or SiNx is formed on the substrate 200. The thin film 230 can be formed by a plasma-enhanced chemical vapor deposition (PECVD) process.

As shown in FIG. 2d, a first electrode 250 is formed in such a manner as to contact with the surface of the substrate 200 on which the second conductive impurity has been diffused. A second electrode 270 is formed on the opposite surface to the first electrode 250.

Next, the following detailed description will focus on a case where the embodiment of present invention is using the single, crystalline substrate or the poly crystalline substrate which has been doped with the first conductive impurity.

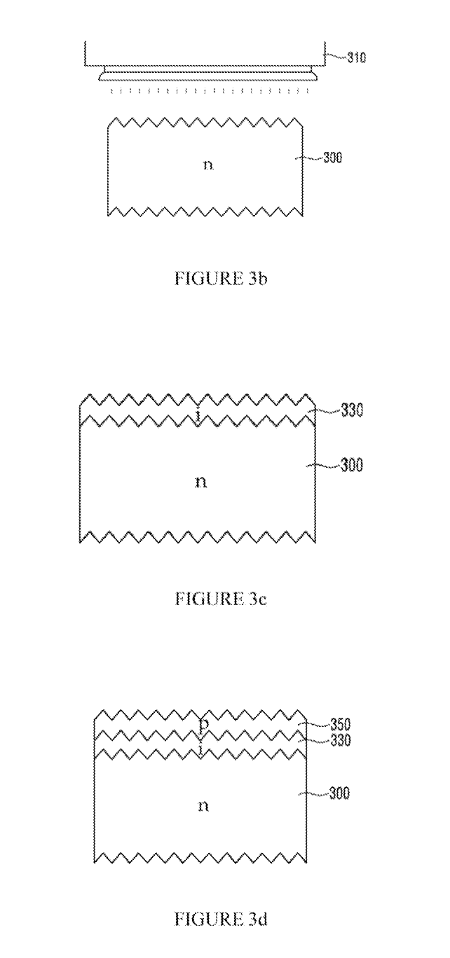

As shown in FIG. 3a, provided is the single crystalline substrate 300 or the poly crystalline substrate 300 which has been doped with a first conductive impurity. Here, although FIG. 3a shows that the substrate 300 is doped with an n-type impurity, the substrate 300 can be doped with a p-type impurity. In order to reduce the amount of reflected light by scattering sunlight incident on the surface of a substrate 300, a texturing process is performed on the surface of the substrate 300, so that the surface of the substrate 300 is textured. The texturing process is performed by means of a wet etching process that makes use of an alkaline solution such as KOH or NaOH, or an acid solution such as HNO₃ or HF.

As shown in FIG. 3b, the substrate 300 is heated at atmosphere by a non-contact heater 310. The non-contact heater 310 may include an infrared (IR) oven.

With the intention of activating an interface between the substrate 300 and the intrinsic amorphous silicon layer to be formed later on the substrate 300, of increasing the passivation effect at, the interface, and of removing moisture of the substrate 300, the substrate 300 is heated at atmosphere by the non-contact heater 310 before the intrinsic amorphous silicon layer is formed on the substrate 300. As described above, since the substrate 300 is heated at atmosphere without contacting with the heater, the substrate can be heated during the transfer thereof without having to maintain vacuum for heating.

The temperature of the substrate 300 is equal to or higher than 120° and is equal to or lower than 180° during the heating process of the substrate 300. The substrate 300 is heated for equal to or greater than 60 seconds and equal to or less than 600 seconds. When the temperature of the substrate 300 is equal to, or higher than 120° and the heating time of the substrate 300 is equal to or greater than 60 seconds, the moisture of the substrate 300 can be fully removed. When the temperature of the substrate 300 is equal to or lower than 180° and the heating time of the substrate 300 is equal to or less than 600 seconds, it is possible to reduce the thermal damage of the interface between the substrate 300 and the intrinsic amorphous silicon layer 330 that is formed in the following process.

As shown in FIG. 3c, the intrinsic amorphous silicon layer 330 is formed on the substrate 300 doped with the first conductive impurity. The intrinsic amorphous silicon layer 330 is formed by injecting silane gas and hydrogen gas into a CVD chamber. The intrinsic amorphous silicon layer 330 reduces defect density at an interface between the first conductive impurity-doped substrate 306, and a second conductive impurity-doped amorphous silicon layer 350 to be formed later, and then prevents the recombination of electrons and holes. Here, the intrinsic amorphous silicon layer 330 may include from 5 to 30 atomic % (atomic percent) of oxygen. When the intrinsic amorphous silicon layer 330 includes from 5 to 30 atomic % of oxygen, epitaxial growth is prevented at the interface between the intrinsic amorphous silicon layer 330 and the single or poly crystalline substrate 300, and the passivation effect can be increased.

As shown in FIG. 3d, a second conductive impurity-doped amorphous silicon layer 350 is formed on the intrinsic amorphous silicon layer 330. The second conductive impurity doped amorphous silicon layer 350 forms an electric field.

As shown in FIG. 3e, a first electrode 370 is formed in such a manner as to contact with the amorphous silicon layer 350 doped with the second conductive impurity. A second electrode 390 is formed on the opposite side to the first electrode 370.

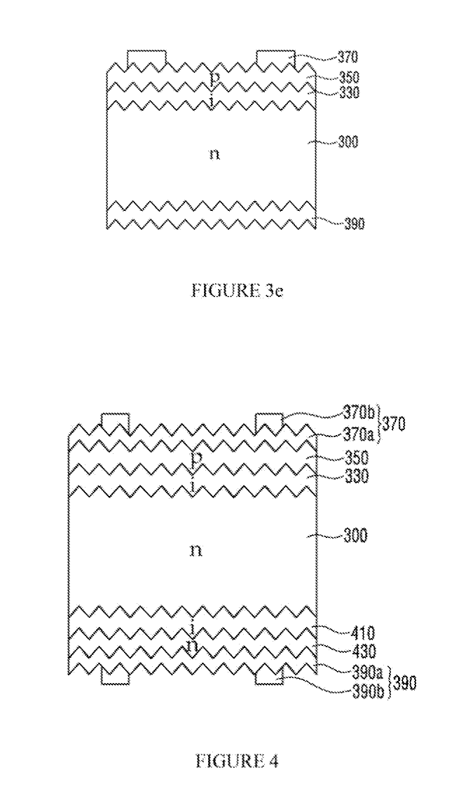

Meanwhile, as shown in FIG. 4, the solar cell of the embodiment of the present invention may further include another intrinsic amorphous silicon layer 410 and an amorphous silicon layer 430 doped with the first conductive impurity, all of which are located between the substrate 300 and the second electrode 390. The intrinsic amorphous silicon layer 410 may be formed prior to the second conductive impurity-doped-amorphous silicon layer 350. The intrinsic amorphous silicon layer 410 increases the passivation effect at the interface between the substrate 300 and the intrinsic amorphous silicon layer 410. The first conductive impurity-doped amorphous silicon layer 430 forms a back surface field (BSF).

Moreover, the first electrode 370 may include a transparent conductive oxide layer 370a such as ZnO or indium tin oxide (ITO), and a collector electrode 370b formed on the transparent conductive oxide layer 370a. The second electrode 390 may also include a transparent conductive oxide layer 390a and a collector electrode 390b formed on the transparent conductive oxide layer 390a. The transparent conductive oxide layers 370a and 390a can be formed by a sputtering method. The collector electrodes 370b and 390b can be formed by a screen printing method. The transparent conductive oxide layers 370a and 390a have resistances greater than those of the collector electrodes 370b and 390b. So the collector electrodes 370b and 390b help the generated electric current flow easily.

While the embodiment of the present invention has been described with reference to the accompanying drawings, it can be understood by those skilled in the art that the present invention can be embodied in other specific forms without departing from its spirit or essential characteristics. Therefore, the foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures.

What is claimed is:

1. A method for heating a substrate of a solar cell, the method comprising:
providing a single or poly crystalline substrate;
heating the substrate at atmosphere by a non-contact heater; and
forming a thin film, which includes amorphous silicon or silicon alloy, on the substrate.

2. The method of claim 1, wherein the non-contact heater comprises an infrared (IR) oven.

3. The method of claim 1, wherein the substrate is heated during the transfer of the substrate.

4. The method of claim, wherein the single or poly crystalline substrate comprises a surface that is textured.

5. The method of claim 4, wherein the surface of the single or poly crystalline substrate, is textured by a wet etching process using an alkaline solution such as KOH or NaOH, or an acid solution such as HNO₃ or HF.

6. A method for heating a substrate of a solar cell, the method comprising:
providing a single or poly crystalline substrate which has been doped with a first conductive impurity and a second conductive impurity;
heating the substrate at atmosphere by a non-contact heater; and
forming a thin film, which includes silicon alloy, on the substrate.

7. The method of claim 6, wherein the refractive index of the silicon alloy is less than that of the substrate.

8. The method of claim 6, wherein the non-contact heater comprises an infrared (IR) oven.

9. The method of claim 6, wherein the temperature of the substrate which is being heated is equal to or higher than 120° and is equal to or lower than 200°, and the substrate is heated for equal to or greater than 60 seconds and equal to or less than 600 seconds.

10. The method of claim 6, wherein the substrate is heated during the transfer of the substrate.

11. The method of claim 6, wherein the silicon alloy comprises SiOx or SiNx.

12. The method of claim wherein the single or poly crystalline substrate comprises a surface that is textured.

13. The method of claim 12, wherein the surface of the single or poly crystalline substrate is textured by a wet etching process using an alkaline solution such as KOH or NaOH, or an acid solution such as HNO₃ or HF.

14. A method for heating a substrate of a solar cell, the method comprising:
providing a single or poly crystalline substrate which has been doped with a first conductive impurity;
heating the substrate at atmosphere by a non-contact heater;
forming an intrinsic amorphous silicon layer on the substrate; and
forming a second conductive impurity doped-amorphous silicon layer on the intrinsic amorphous silicon layer.

15. The method of claim 14, wherein the non-contact heater comprises an infrared (IR) oven.

16. The method of claim 14, wherein the temperature of the substrate which is being heated is equal to or higher than 120° and is equal to or lower than 180°, and the substrate is heated for equal to or greater than 60 seconds and equal to or less than 600 seconds.

17. The method of claim 14, wherein the substrate is heated during the transfer of the substrate.

18. The method of claim 14, wherein the intrinsic amorphous silicon layer comprises from 5 to 30 atomic % of oxygen.

19. The method of claim 14, wherein the single or poly crystalline substrate comprises a surface that is textured.

20. The method of claim 19, wherein the surface of the single or poly crystalline substrate is textured by a wet etching process using an alkaline solution such as KOH or NaOH, or an acid solution such as HNO₃ or HF.
